(19) United States
(12) Patent Application Publication
(10) Pub. No.: US 2016/0266971 A1
(43) Pub. Date: Sep. 15, 2016

(54) MEMORY SYSTEM, MEMORY CONTROLLER AND MEMORY CONTROL METHOD

(71) Applicant: Kabushiki Kaisha Toshiba, Minato-ku (JP)

(72) Inventors: Osamu TORII, Setagaya (JP); Daiki Watanabe, Yokohama (JP)

(73) Assignee: Kabushiki Kaisha Toshiba, Minato-ku (JP)

(21) Appl. No.: 14/845,875

(22) Filed: Sep. 4, 2015

Related U.S. Application Data
(60) Provisional application No. 62/130,902, filed on Mar. 10, 2015.

(51) Int. Cl. G06F 11/10; H03M 13/29; G11C 29/52

(52) U.S. Cl. CPC G06F 11/1068; G11C 29/52; H03M 13/2909

(57) ABSTRACT

According to an embodiment, a memory system includes a nonvolatile memory, a correction unit, a storage unit, and an update unit. The correction unit performs error correction on code words forming a product code that is read from the nonvolatile memory. The storage unit stores a first code word, the first code words being the code word on which the error correction is not yet performed by the correction unit. The update unit updates, in case where a condition is satisfied, first data to second data, the first data being included in a second code word, the second code word being the code word on which the error correction is performed, the first data being corrected by the error correction, the second data being included in the first code word, the second data corresponding to the first data.

### CROSS-REFERENCE TO RELATED APPLICATIONS

This application is based upon and claims the benefit of priority from U.S. Provisional Application No. 62/130,902, filed on Mar. 10, 2015; the entire contents of which are incorporated herein by reference.

### FIELD

Embodiments of described herein generally relate to a memory system, a memory controller and a memory control method.

### BACKGROUND

When user data stored in a nonvolatile memory is read from the memory, a phenomenon in which the read user data is changed to a value other than an original value or the like may occur.

In order to cope with this problem, a method of performing error-correction encoding on user data to generate parity data and managing the user data and the parity data as a set is generally used. A Bose Chaudhuri Hocquenghem (BCH) code or Reed-Solomon (RS) code is used as an error correcting code. A product code has been proposed as a method of combining codes to improve correction capability.

### BRIEF DESCRIPTION OF THE DRAWINGS

FIG. 1 is a block diagram illustrating a configuration example of a memory system according to a first embodiment;

FIG. 2 is a diagram illustrating a configuration example of a product code which is generated by an encoder unit in the first embodiment;

FIG. 3 is a diagram illustrating a pattern formed when error correction is performed on user data in the first embodiment;

FIG. 4 is a block diagram illustrating a configuration of a decoder unit, a DRAM, and a semiconductor memory in the first embodiment;

FIG. 5 is a diagram illustrating a state in which rollback control is performed because an inversion number is greater than a reference value when generation of a component code word by error correction succeeds in the first embodiment;

FIG. 6 is a diagram illustrating a state in which rollback control is performed depending on a relation to another component code when generation of a component code word by error correction succeeds in the first embodiment;

FIG. 7 is a diagram illustrating a state in which rollback control is performed based on a calculation result of a code word of a component code in another direction which is subsequently performed when generation of a component code word by error correction succeeds in a modified example;

FIG. 8 is a diagram illustrating a state in which rollback control is performed based on a calculation result of a code word of a component code in another direction which is subsequently performed when generation of a component code word by error correction succeeds in a modified example;

FIG. 9 is a diagram illustrating another state in which rollback control is performed in a memory controller according to a modified example;

FIG. 10 is a diagram illustrating a case in which generation of a component code word by error correction fails in the first embodiment;

FIG. 11 is a flowchart illustrating a process flow up to rollback control in a memory controller according to the first embodiment;

FIG. 12 is a block diagram illustrating a configuration of a controller, a DRAM, and a semiconductor memory according to a second embodiment;

FIG. 13 is a diagram illustrating a flow of determining a rollback control target in a component code dynamic determining unit in the second embodiment;

FIG. 14 is a diagram illustrating rollback control in a dynamic update unit when generation of a code word by error correction fails in the second embodiment;

FIG. 15 is a diagram illustrating a flow of recursively determining a component code word to be subjected to rollback control in the component code dynamic determining unit in the second embodiment;

FIG. 16 is a flowchart illustrating a process flow up to rollback control in a memory controller according to the second embodiment; and

FIG. 17 is a flowchart illustrating a rollback control flow in a decoder unit in the second embodiment.

### DETAILED DESCRIPTION

According to an embodiment, a memory system includes a nonvolatile memory, a correction unit, a storage unit, and an update unit. The correction unit performs error correction on code words forming a product code that is read from the nonvolatile memory. The storage unit stores a first code word, the first code words being the code word on which the error correction is not yet performed by the correction unit. The update unit updates, in case where a condition is satisfied, first data to second data, the first data being included in a second code word, the second code word being the code word on which the error correction is performed, the first data being corrected by the error correction, the second data being included in the first code word stored in the storage unit, the second data corresponding to the first data.

Hereinafter, a memory system, a memory controller and a memory control method according to embodiments will be described in detail with reference to the accompanying drawings. The present invention is not limited to the embodiments.

### First Embodiment

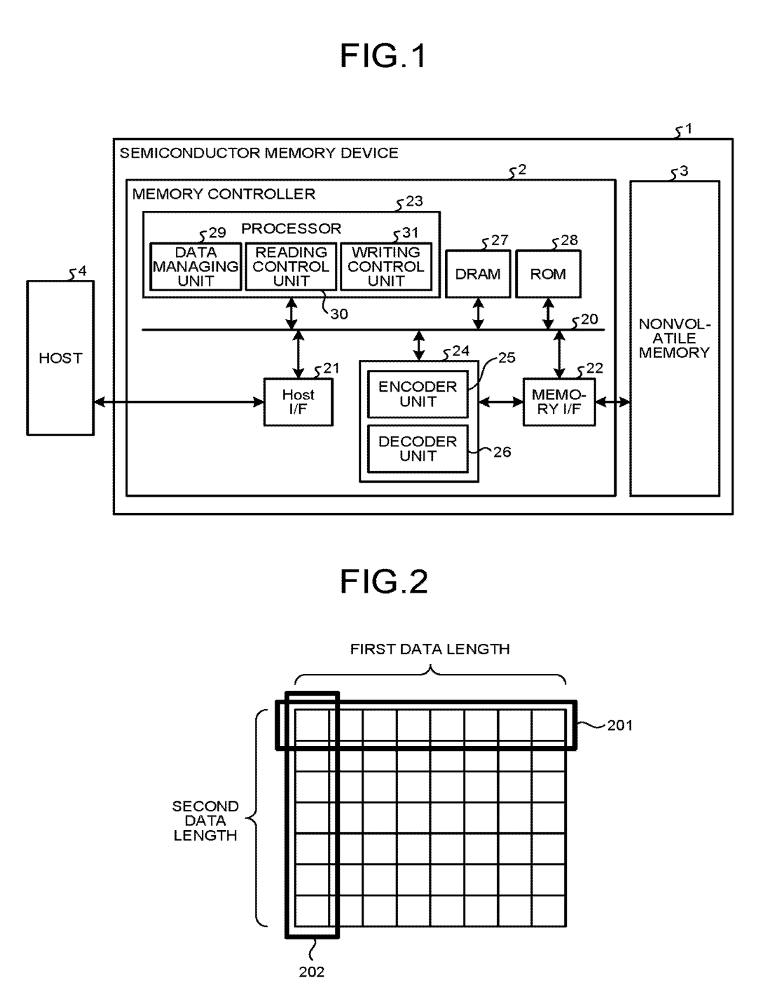

FIG. 1 is a block diagram illustrating a configuration example of a memory system according to a first embodiment. A semiconductor memory device (storage device) 1 according to this embodiment includes a memory controller 2 and a nonvolatile memory 3. The storage device 1 can be connected to a host 4 and a state in which the storage device is connected to the host 4 is illustrated in FIG. 1. The host 4 is, for example, an electronic device such as a personal computer or a portable terminal. The semiconductor memory device (storage device) 1 according to this embodiment may be a memory card or a solid state drive (SSD) in which the memory controller 2 and the nonvolatile memory 3 are incorporated into a package.

The nonvolatile memory 3 is a memory that stores data in a nonvolatile manner and is, for example, a NAND memory. An example in which a NAND memory is used as the nonvolatile memory 3 is described therein, but a storage unit other than the NAND memory, such as a three-dimensional flash memory, a resistance random access memory (ReRAM), and a ferroelectric random access memory (FeRAM), may be used as the nonvolatile memory 3. In this embodiment, an example in which a nonvolatile memory is used as a storage unit is described, but a nonvolatile memory in which an error correction process of this embodiment is applied to a storage unit other than the nonvolatile memory may be employed.

The memory controller 2 controls writing to the nonvolatile memory 3 in accordance with a writing command (command) from the host 4 and controls reading from the nonvolatile memory 3 in accordance with a reading command (command) from the host 4. The memory controller 2 includes a host I/F 21, a memory I/F 22, a processor 23, an encoder/decoder unit 24, and a dynamic random access memory (DRAM) 27. The encoder/decoder unit 24 includes an encoder unit 25 and a decoder unit 26. The host I/F 21, the memory I/F 22, the processor 23, the encoder unit 25, the decoder unit 26, the DRAM 27, and a read only memory (ROM) 28 are connected to each other via an internal bus 20. The ROM 28 stores firmware to be executed by the processor 23 or the like.

The processor 23 comprehensively controls elements of the semiconductor memory device 1. The function of the processor 23 realizes a data managing unit 29, a reading control unit 30, and a writing control unit 31, for example, by executing the firmware stored in the ROM 28 or the like. Accordingly, the memory controller 2 can perform reading of data from the nonvolatile memory 3 or writing of data to the nonvolatile memory 3 in accordance with a command from the host 4. The data managing unit 29, the reading control unit 30, and the writing control unit 31 may be realized by hardware. The storage destination of the firmware is not limited to the ROM 28, but may be the nonvolatile memory 3.

The data managing unit 29 manages the position in the nonvolatile memory 3 at which data is stored. The data managing unit 29 includes an address conversion table (not illustrated) in which logical addresses given from the host 4 are correlated with physical positions in the nonvolatile memory 3, and perform garbage collection depending on usage of blocks in the nonvolatile memory 3.

The reading control unit 30 performs control of reading data from the nonvolatile memory 3 in accordance with a command transmitted from the host 4 via the host I/F 21. For example, the reading control unit 30 acquires a physical position in the nonvolatile memory 3 corresponding to a logical address of read data from the data managing unit 29 and notifies the memory I/F 22 of the physical position. The read data is transmitted to the host 4 via the decoder unit 26 and the DRAM 27.

The writing control unit 31 performs a process of writing data to the nonvolatile memory 3 in accordance with a command transmitted from the host 4 via the host I/F 21. For example, the writing control unit 31 acquires a physical position in the nonvolatile memory 3 to which data will be written from the data managing unit 29 and outputs the physical position and a code word output from the encoder unit 25 to the memory I/F 22.

The host I/F 21 performs a process based on an interface standard with the host 4 and outputs command received from the host 4, user data, and the like to the internal bus 20. The host I/F 21 transmits user data read from the nonvolatile memory 3, a response from the controller 23, and the like to the host 4.

The memory I/F 22 controls the process of writing data to the nonvolatile memory 3 and the process of reading data from the nonvolatile memory 3 based on an instruction of the controller 23.

The DRAM 27 is used as an area in which user data are temporarily stored when the user data is read or the user data is written. For example, the DRAM 27 is used as a storage unit storing user data on which error correction is not yet performed by the decoder unit 26 and user data on which the error correction is performed when the error correction is performed on the user by the decoder unit 26. In this embodiment, the area in which the user data is temporarily stored is not limited to the DRAM. For example, a static random access memory (SRAM) may be used as the area in which the user data is temporarily stored. The DRAM 27 is installed in the memory controller 2 in this embodiment, but may be installed independently of the memory controller 2. The DRAM may be embodied as a built-in memory in a chip of the memory controller 2.

The controller 23 is a control unit comprehensively controlling the elements of the semiconductor memory device 1. The controller 23 performs control based on a command when the command is received from the host 4 via the host I/F 21.

For example, when a writing command is received from the host 4, the controller 23 determines a storage area (memory area) in the nonvolatile memory 3 for user data stored in the DRAM 27. The controller 23 manages a writing destination of user data. Correspondence between the logical address of the user data received from the host 4 and the physical address indicating the storage area in the nonvolatile memory 3 in which the user data is stored as an address conversion table. When a writing command is received from the host 4, the controller 23 instructs the encoder unit 25 to encode the user data. When a reading command is received from the host 4, the controller 23 converts a logical address designated by the reading command into a physical address using the address conversion table, and instructs the memory I/F 22 to read the user data from the physical address. When a reading command is received from the host 4, the controller instructs the memory I/F 22 to read a code word from the nonvolatile memory 3 and instructs the decoder unit 26 to perform error correction using the read code word loaded to the DRAM 27.

In a NAND memory, writing units (minimum writing) called a page are generally present, writing and reading are performed by pages, and erasing is performed by data units called a block. When the nonvolatile memory 3 is a NAND memory, the nonvolatile memory 3 includes plural word lines, and plural memory cells (memory cell transistors) are connected to the word lines. In this embodiment, memory cells connected to the same word line are referred to as a memory cell group. When a memory cell is a single-level cell (SLC), one memory cell group corresponds to one page. When a memory cell is a multi-level cell (MLC), one memory cell group corresponds to plural pages. Each memory cell is connected to a word line and a bit line. Each memory cell can be identified by an address for identifying a word line and an address for identifying a bit line.

The encoder unit 25 performs an error correction encoding process based on the user data stored in the DRAM 27 to generate a code word. The encoder unit 25 of this embodiment uses a product code that improves correction capability as a method of combining codes. Error correction codes to be combined are not particularly limited and, for example, a Bose Chaudhuri Hocquenghem (BCH) code or a Reed-Solomon (RS) code can be used. For example, the RS code and the BCH code may be combined, and different types of codes may be combined in this way.

FIG. 2 is a diagram illustrating a configuration example of a product code generated by the encoder unit 25 of this embodiment. The encoder unit 25 generates a code word in the row direction illustrated in FIG. 2 by the number of rows forming the product code. A code word 201 is an example of the code word in the row direction. The encoder unit 25 generates a code word in the column direction by the number of columns forming the product code. A code word 202 is an example of the code word in the column direction. For example, the encoder unit 25 encodes user data of a first data length to generate a component code word in the row direction. The encoder unit encodes user data of a second data length including data of each of plural component code words in the row direction to generate a component code word in the column direction. In the product code, the user data is doubly protected by two code words of the component code word in the column direction and the component code word in the row direction.

In other words, the product code can be called a code word including plural first component code words in the row direction and plural second component code words in the column direction. In this embodiment, the first component code words in the row direction are generated based on a second data row including plurality of pieces of first data (for example, bits) as a unit for correction. In this embodiment, the second component code words in the column direction are generated based on a third data column including plurality of pieces of first data (for example, bits) as a unit for correction, which are respectively selected from plural second data rows. One piece of first data (for example, bit) included in one third data column does not duplicate with another piece of first data (for example, bit) included in another third data column.

The decoder unit 26 performs an error correction process of a product code based on the code words read from the nonvolatile memory 3. The error correction process includes a decoding process and a process of correcting a bit value (inverting the bit value) at an error position calculated through the decoding process. The decoder unit 26 outputs user data on which the error correction process is performed to the internal bus 20. The decoder unit 26 acquires a code word read out of the nonvolatile memory 3 from the memory I/F 22 and decodes the acquired code word. The decoder unit 26 notifies the reading control unit 30 of a reading error when the error correction in the decoding fails.

In this embodiment, when user data is written to the nonvolatile memory 3 in units of a page, the encoding using a product code is performed to generate a code word in units of a page, but the product code may be formed in units of plural pages or plural product codes may be included in one page. In this embodiment, the BCH codes are used as the codes in the row direction and the column direction of a product code, but another code may be used. In this embodiment, a product code is used as an error correction target, but another code may be used as an error correction target.

When a product code is used, an error of user data is corrected by iterating calculation for each component code at the time of decoding. The component code means a row code or a column code in a product code. That is, a component code in the column direction means the entire code words in the column direction (code words in the column direction corresponding to the number of columns forming the product code), and a component code in the row direction means the entire code words in the row direction (code words in the row direction corresponding to the number of rows forming the product code). The component code words mean code words of each component code. The decoder unit 26 performs calculation (error correction process) of each component code word of the component code in the row direction and then performs calculation of each component code word of the component code in the column direction when a non-corrected error remains. The decoder unit 26 performs calculation of each component code word of the component code in the column direction and then performs calculation the component code in the row direction when a non-corrected error remains. By iterating the calculation for each component code in this way, an error of the user data forming the product code is reduced. However, even when the calculation of the component code words succeeds, the code word acquired by the calculation of the component code words may not be a correct code word (the user data written to the nonvolatile memory 3 may not be correctly reconstructed).

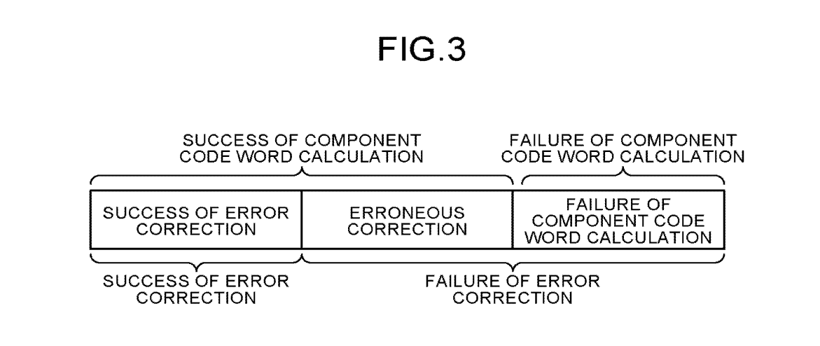

FIG. 3 is a diagram illustrating a pattern formed when error correction is performed on user data.

In FIG. 3, a case in which a correct code word is acquired by performing calculation of the component code of an arbitrary column or row is indicated to be “success of component code word calculation”. On the other hand, a case in which a component code word is not acquired by performing calculation of the component code in an arbitrary column or row is indicated to be “failure of component code word calculation”

Even when a correct code word is acquired by “success of component code word calculation”, the user data may be erroneous. In this embodiment, a case in which the component code word calculation succeeds but the code word acquired as the calculation result is not correct is called “erroneous correction”. In case of erroneous correction, since the component code word calculation succeeds but the code word acquired as the calculation result is not correct, the error correction actually fails.

That is, when “success of component code word calculation” is resulted and correct user data is acquired, the error correction succeeds. When the erroneous correction is resulted or the component code word calculation fails, the error correction fails.

The memory controller 2 according to this embodiment performs control of updating user data on which calculation is performed to user data on which the calculation is not yet performed in the case of the erroneous correction or the failure of component code word calculation. In this embodiment, the control of updating the user data on which calculation is performed to the user data on which the calculation is not yet performed is referred to as rollback control.

In a component code word calculation method which is generally used, for example, a component code word calculation method called a bounded distance decoding algorithm, or the like, when the component code word calculation succeeds, it is difficult to determine whether the code word acquired as the calculation result is correct. That is, it is difficult to determine whether erroneous correction occurs.

Therefore, the decoder unit 26 of the memory controller 2 according to this embodiment sets a condition in which there is a possibility that erroneous correction occurs, considers that there is a possibility that erroneous correction occurs when the condition is satisfied, and performs rollback control. The decoder unit 26 performs the rollback control even when the component code word calculation fails.

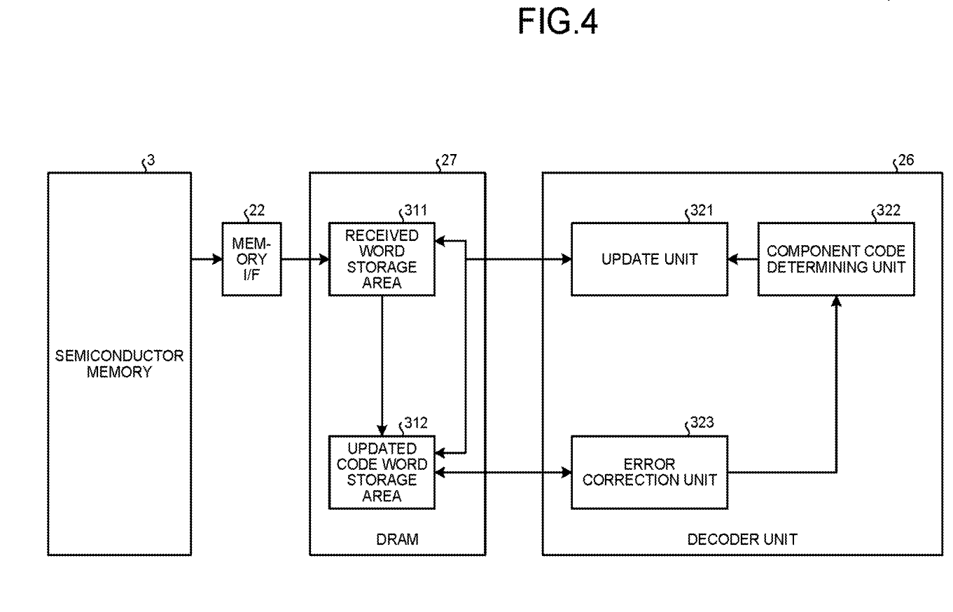

A configuration realized in the decoder unit 26 and the DRAM 27 will be described below. FIG. 4 is a block diagram illustrating the configuration in the decoder unit 26 and the DRAM 27. A received word storage area 311 and an updated code word storage area 312 are installed in the DRAM 27. The decoder unit 26 includes an update unit 321, a component code word determining unit 322, and an error correction unit 323. The decoder unit 26 may be realized by a processor and may realize the update unit 321, the component code determining unit 322, and the error correction unit 323 by executing a program (not illustrated). The controller 23 may include the update unit 321, the component code word determining unit 322.

The memory I/F 22 transmits a code word stored in the nonvolatile memory 3 to the DRAM 27 in response to a reading command of user data from the host 4.

The received word storage area 311 is an area in which a received word (code word) received from the nonvolatile memory 3 in response to the reading command via the memory I/F 22 is temporarily stored. In other words, the received word storage area 311 stores a code word (data) on which error correction is not yet performed by the error correction unit 323.

The updated code word storage area 312 is an area in which a code word acquired by performing the component code word calculation on the code word stored in the received word storage area 311 is stored. In this embodiment, when a code word is read to the received word storage area 311, the code word is copied to the updated code word storage area 312. Thereafter, the error correction unit 323 performs error correction using the code word stored in the updated code word storage area 312. In this embodiment, the entire product code is stored in the received word storage area 311 and the updated code word storage area 312 of the DRAM 27, but only partial data instead of the entire product code may be stored.

Based on a product code read from the nonvolatile memory 3 and then stored in the updated code word storage area 312, the error correction unit 323 performs the error correction of code words forming the product code for each component code included in the product code.

The error correction unit 323 of this embodiment performs the error correction in the units of a component code word in the column direction among the product code, performs the error correction on all the component code words in the column direction, performs the error correction in the units of a component code word in the row direction, and performs the error correction on all the component code words in the row direction. The error correction unit 323 of this embodiment alternately iterates the error correction of the plural component code words in the column direction and the error correction of the plural component code words in the row direction.

The component code determining unit 322 determines whether the result of the error correction performed by the error correction unit 323 satisfies a rollback control condition for each component code word on which the error correction is performed.

When the rollback control condition is satisfied, the update unit 321 updates at least some data included in the code word on which the error correction is performed by the error correction unit 323 to data included in the code word on which the error correction is not performed and stored in the received word storage area 311. In other words, the update unit 321 performs rollback control.

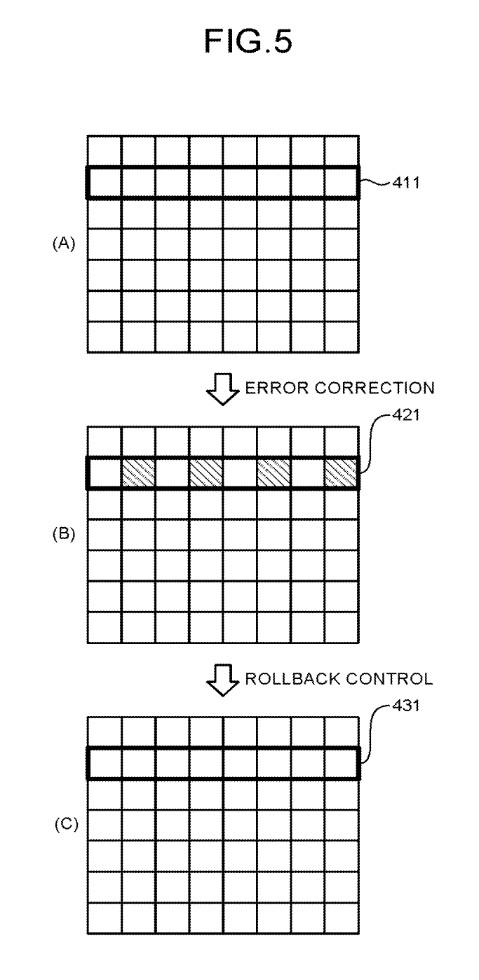

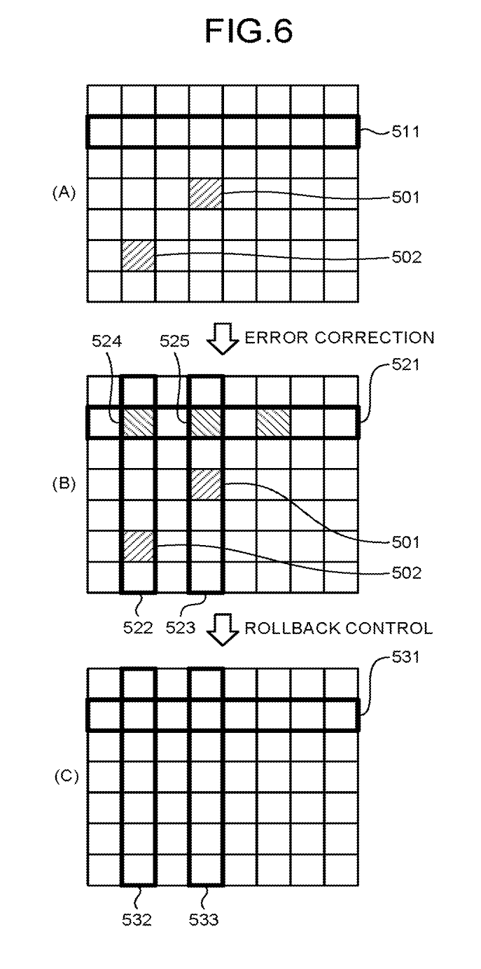

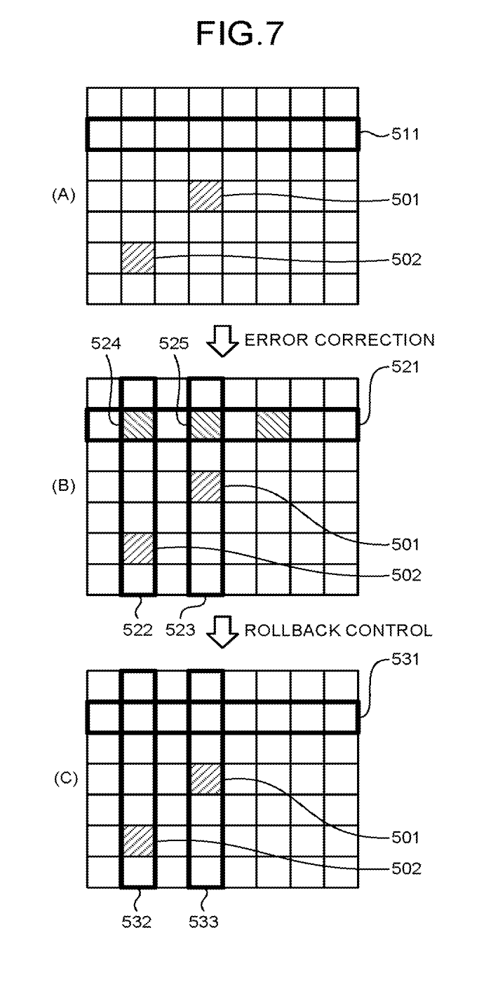

A condition (rollback condition) for determining a code word to be rolled back in the rollback control will be described below with reference to FIGS. 5, 6, and 7. FIGS. 5 and 6 illustrate two examples of the rollback condition when the newest error correction of a code word to be subjected to an error correction process succeeds, and FIG. 7 illustrates a rollback condition when the newest error correction of a code word to be subjected to an error correction process fails.

FIG. 5 is a diagram illustrating a state in which the rollback control is performed because an inversion number is equal to or greater than a reference value (threshold value) i when generation of a component code word by the error correction succeeds in the first embodiment. The inversion number means the number of minimum data units (for example, one bit), which can be corrected by the error correction, inverted (corrected) by the error correction. It is assumed that a right-inclined hatched block is data which is inverted by the error correction of a row component code and a left-inclined hatched block is data which is inverted by the error correction of a column component code.

The component code determining unit 322 of this embodiment determines that an erroneous correction probability is high when the inversion number of pieces of data on which error correction is performed by the error correction unit 323 among the component code words is equal to or greater than a predetermined reference value i. In the example illustrated in FIG. 5, the reference value is assumed to be i=4. In this embodiment, it is assumed that the number of pieces of data on which the error correction can be performed using the component code words forming the product code is greater than 4.

The product code acquired by processing a row component code word 411 in (A) of FIG. 5 as an error correction target of the error correction unit 323 is illustrated in (B) of FIG. 5.

In (B) of FIG. 5, it can be seen that four pieces of inverted data are included in a component code word 421 in the row direction on which the error correction is performed, that is, the inversion number is four. Accordingly, the component code determining unit 322 determines that the condition of inversion number reference value i is satisfied. Accordingly, the rollback control is performed by the update unit 321. The result of the rollback control is illustrated in (C) of FIG. 5.

In (C) of FIG. 5, it can be seen that the data inverted by the error correction disappears in a row component code word 431 subjected to the rollback control.

In this way, in the example illustrated in FIG. 5, the component code determining unit 322 sets the rollback control condition to whether the inversion number is equal to or greater than the predetermined reference value (threshold value) i. When the condition is satisfied, the update unit 321 updates the data on which the error correction is performed by the error correction unit 323 to the data on which the error correction is not performed and stored in the received word storage area 311.

That is, in the example illustrated in FIG. 5, when the error correction of a component code word succeeds and the inversion number in the component code word on which the error correction is performed is equal to or greater than the reference value i, it is considered that there is a high possibility that the erroneous correction is performed and the rollback control of the component code word is performed. Accordingly, it is possible to suppress progress of the erroneous correction. The reference value i in this embodiment is determined in advance, but may be determined, for example, based on the number of times of error correction iterated by the error correction unit 323.

FIG. 6 is a diagram illustrating a state in which the rollback control is performed based on the calculation result of a code word of a component code in the other direction which is subjected subsequently when generation of a component code word by the error correction succeeds in the first embodiment.

In (A) of FIG. 6, data on which the error correction is performed in column component code words is a plurality of pieces of data 501 and 502. A row component code word 511 is an error correction target of the error correction unit 323. The result of the error correction is illustrated in (B) of FIG. 6.

In (B) of FIG. 6, three pieces of inverted data are included in a component code word 521 in the row direction. Two pieces of the inverted data are a plurality of pieces of data 524 and 525, and the plurality of pieces of data 524 and 525 are included in component code words 522 and 523 in the column direction. However, in the error correction of the component code words 522 and 523 in the column direction, the plurality of pieces of data 501 and 502 are inverted but the plurality of pieces of data 524 and 525 are not inverted. That is, the plurality of pieces of data 524 and 525 which are not inverted when the error correction is performed on the component code words 522 and 523 in the column direction are inverted by the current error correction of the row component code word 521. In this case, it is considered that the erroneous correction is performed by at least one of the error correction of the component code words 522 and 523 in the column direction and the error correction of the component code word 521 in the row direction.

Therefore, in the example illustrated in FIG. 6, the component code determining unit 322 sets the rollback control condition to a case in which at least some data which forms the code words of the component code in one direction of the column direction and the row direction and which are not corrected when the error correction of code words of the component code in one direction is performed is subjected to the error correction at the time of error correction of code words of the component code which include the data in the other direction.

In other words, in this embodiment, the rollback control condition is set to a case in which a bit, on which the error correction is not yet performed, among plural bits (plurality of pieces of first data) included in one component code word of the plural component code words in a first direction (for example, the column direction or the row direction) is corrected by the error correction of another component code word which includes the bit on which the error correction is not yet performed and which is one of the plural component code words in a second direction (the column direction or the row direction which is a direction other than the first direction).

Then, the update unit 321 updates the data on which the error correction is performed by the error correction unit 323 among the data included in the code words of the component code in one direction and the component code in the other direction to the data on which the error correction is not performed and stored in the received word storage area 311.

In this way, the rollback control is performed by the update unit 321. The result of the rollback control is illustrated in (C) of FIG. 6.

In (C) of FIG. 6, it can be seen that the data inverted by the error correction disappears in a component code 531 in the row direction and component codes 532 and 533 in the column direction.

FIG. 6 illustrates an example in which all the row component code 531 and the column component codes 532 and 533 are subjected to the rollback control, but the rollback control may be performed in only one of the row component code and the column component code. That is, the update unit 321 can update at least one of data, which is not corrected by the error correction in the first direction (for example, the column direction or the row direction) but corrected by the error correction in the second direction (the column direction or the row direction which is a direction other than the first direction) and a bit corrected by the error correction in the first direction to the data on which the error correction is not yet performed.

A memory controller 2 according to a modified example that performs rollback control on any one of a row component code and a column component code will be described below. FIG. 7 is a diagram illustrating a state in which the rollback control is performed based on the calculation result of a component code word in the other direction which is subjected subsequently when generation of a component code word by the error correction succeeds in the modified example. In the example illustrated in FIG. 7, the row component code out of the row component code and the column component code is subjected to the rollback control. In (A) and (B) of FIG. 7, the same processes as in (A) and (B) of FIG. 6 are performed.

In (C) of FIG. 7, the result of the rollback control in the update unit 321 is illustrated. In (C) of FIG. 7, it can be seen that the data which is inverted by the error correction of the component code 531 in the row direction disappears and the data which is inverted by the error correction of the column component codes 532 and 533 (for example, a plurality of pieces of data 501 and 502) is included.

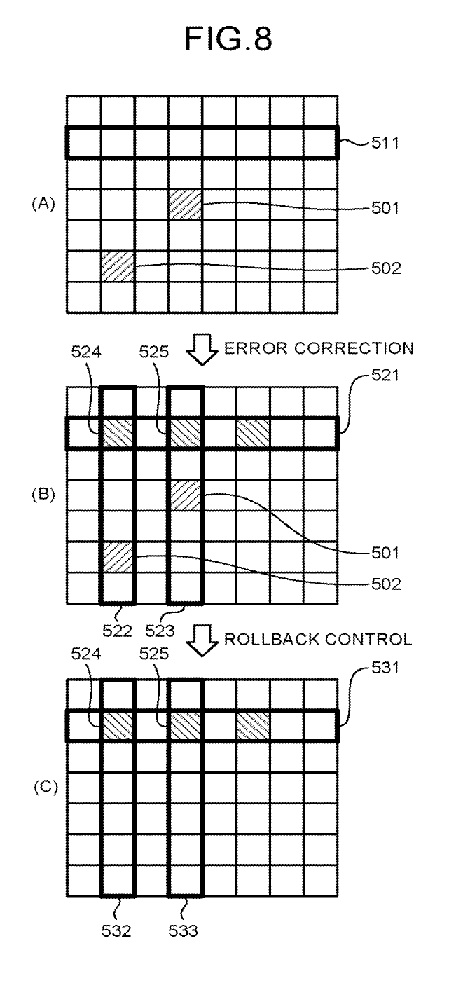

FIG. 8 is a diagram illustrating a state in which the rollback control is performed based on the calculation result of a code word of a component code in the other direction which is subjected subsequently when generation of a component code word by the error correction succeeds in the modified example. In the example illustrated in FIG. 8, the column component code out of the row component code and the column component code is subjected to the rollback control. In (A) and (B) of FIG. 8, the same processes as in (A) and (B) of FIG. 6 are performed.

In (C) of FIG. 8, the result of the rollback control by the update unit 321 is illustrated. In (C) of FIG. 8, it can be seen that the data which is inverted by the error correction of the component codes 532 and 533 in the column direction disappears and the data (for example, a plurality of pieces of data 524 and 525) which is inverted by the error correction of the row component code 531 (for example, a plurality of pieces of data 501 and 502) is included.

In this way, even when the rollback control is performed on any one of the row component code and the column component code, the possibility that a data error will be corrected is improved.

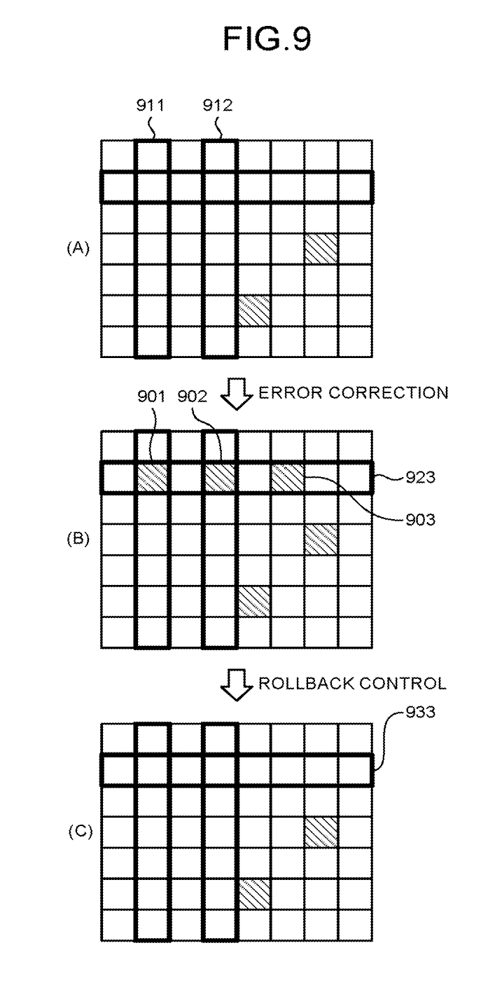

Another state can be considered as the state in which the rollback control is performed. FIG. 9 is a diagram illustrating another state in which the rollback control is performed in the memory controller 2 according to the modified example. In (A) of FIG. 9, it is assumed that column component code words 911 and 912 on which the error correction is not yet performed. In the example illustrated in (B) of FIG. 9, a plurality of pieces of data 901, 902, and 903 are inverted by the error correction of a row component code word 923. Since the plurality of pieces of data 901 and 902 are not corrected by the error correction of the column component code words 911 and 912 but are corrected by the error correction of the row component code word 923, the component code determining unit 322 considers that the probability that the error correction of the row component code 923 is erroneous correction is high. The component code determining unit 322 sets the component code 923 as the rollback control target. The update unit 321 generates a row component code word 933 by performing the rollback control on the row component code 923. Accordingly, the possibility that the data error will be corrected is enhanced.

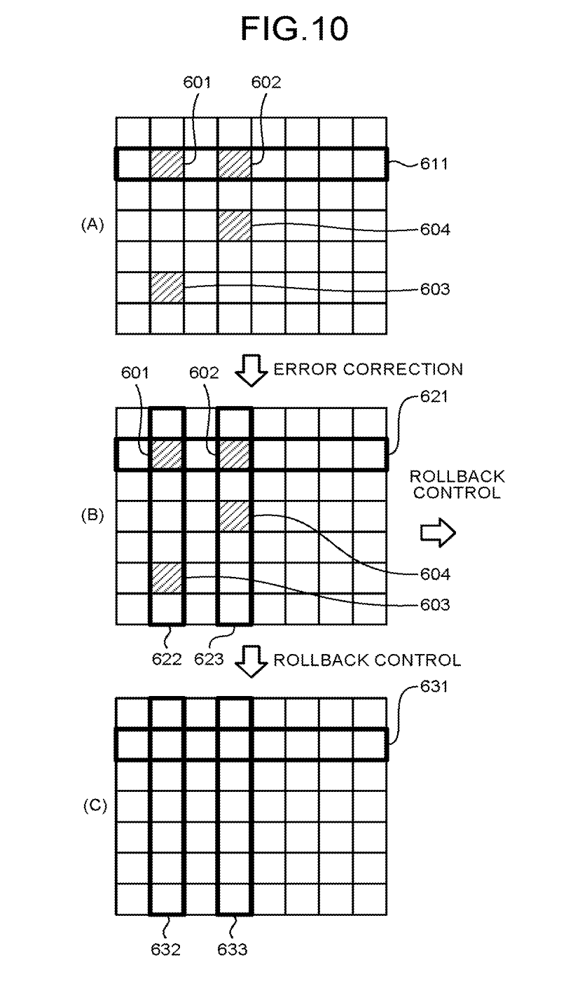

In the first embodiment, a case in which the generation of a component code word by the error correction fails will be described. FIG. 10 is a diagram illustrating a case in which the generation of a component code word in the row direction by the error correction fails.

In (A) of FIG. 10, data which is inverted by the error correction of a component code in the column direction is a plurality of pieces of data 601, 602, 603, and 604. A component code word 611 in the row direction in (A) of FIG. 10 is an error correction target in the error correction unit 323. The result of the error correction of the component code word 611 in the row direction is illustrated in (B) of FIG. 10.

In (B) of FIG. 10, since the error correction of the component code word 611 in the row direction in (A) of FIG. 10 fails, the component code 621 in the row direction subjected to the error correction is not inverted but is maintained in the same state as the component code word 611 due to the failure of error correction. The component code word 621 in the row direction includes the plurality of pieces of data 601 and 602 which are inverted by the error correction of the component code words 622 and 623 in the column direction. Accordingly, it is predicted that there is a possibility that the inversion of the plurality of pieces of data 601 and 602 which has been performed by the error correction of the column component code words 622 and 623 is the erroneous correction and will cause the current error correction of the component code 621 in the row direction. Therefore, the component code determining unit 322 determines the row component code word 621 and the column component code words 622 and 623 to be the rollback control target. Accordingly, the rollback control of the column component code words 622 and 623 is performed by the update unit 321. The result of the rollback control is illustrated in (C) of FIG. 10.

In (C) of FIG. 10, it can be seen that the data which is inverted by the error correction disappears in component code words 632 and 633 in the column direction.

In this way, the component code determining unit 322 sets the rollback control condition to the case in which the error correction is performed on the data included in one component code and then the error correction of another component code having data corrected by the error correction of the one component code fails. When the condition is satisfied, the update unit 321 updates the one component code word to the component code word on which the error correction is not yet performed.

That is, in FIG. 10, the rollback control is performed on the condition that the error correction of another component code word, which includes a bit on which the error correction is performed among plural bits (a plurality of pieces of first data) included in one component code word of plural component code words in the first direction (the row direction or the column direction) and which is one of plural component code words in the second direction (the column direction or the row direction which is a direction other than the first direction), fails. The update unit 321 performs the rollback control on the data corrected by the error correction of the one component code word including the bit on which the error correction is performed.

In this embodiment, the flow of returning the state on which error correction is performed to the state on which the error correction is not yet performed through the rollback control of a component code which is considered the component code on which the error correction is performed by the decoder unit 26 is described. When the error correction is performed on the component code subjected to the rollback control after the error correction of another component code is performed after the rollback control, the condition is different from the condition before the rollback control and thus the possibility that appropriate error correction will be performed is enhanced.

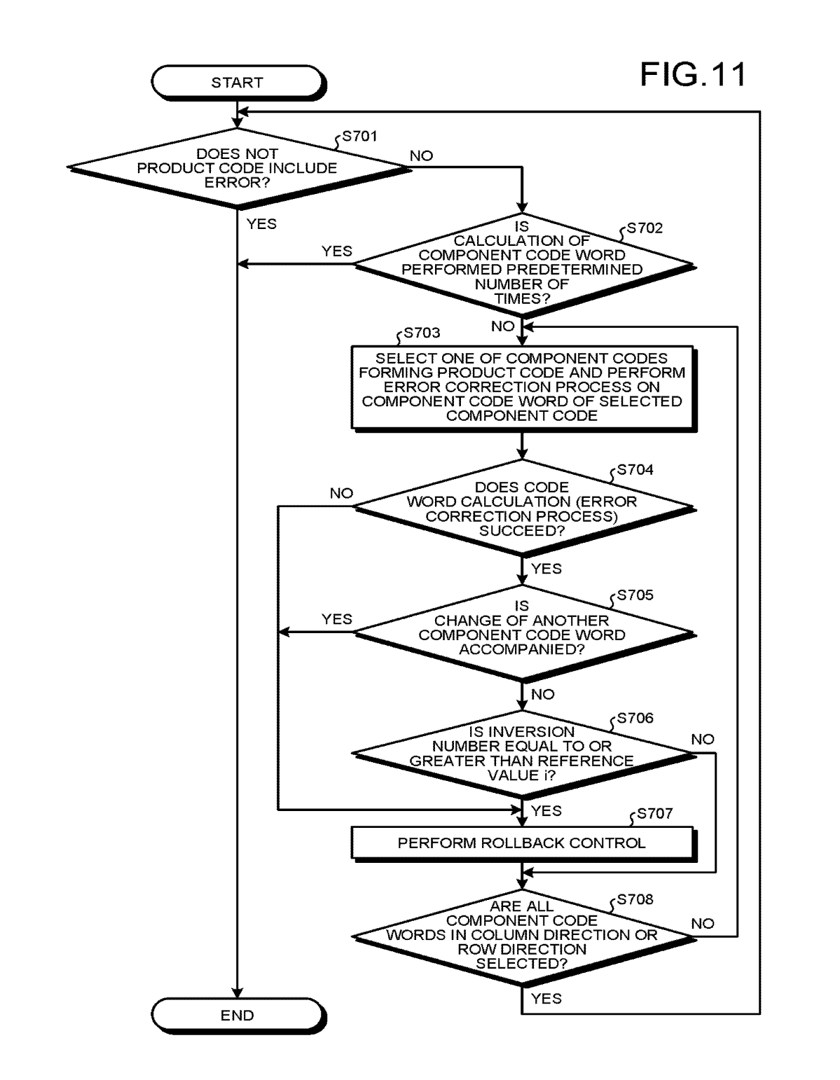

The process flow up to the rollback control in the memory controller 2 according to this embodiment will be described below. FIG. 11 is a flowchart illustrating the process flow in the memory controller 2 according to this embodiment. Before the process flow illustrated in FIG. 11, it is assumed that a product code stored in the nonvolatile memory 3 is loaded to the received word storage area 311 in response to a command from the host 4 and the product code is copied to the updated code word storage area 312.

First, the error correction unit 323 of the decoder unit 26 determines whether the product code stored in the updated code word storage area 312 does not include an error (S701). In S701 of the first time, for example, the entire component code words in the row direction are decoded and it is determined whether the product code does not include an error based on information on error presence or absence acquired by the decoding. When the error correction unit 323 determines that the product code does not include an error (YES in S701), the process flow ends.

On the other hand, when the error correction unit 323 determines that the product code includes an error (NO in S701), the error correction unit 323 determines whether calculation of component codes (error correction process) in the column direction and the row direction is performed on the product code a predetermined number of times (S702). The predetermined number of times may be determined for the number of times of component code calculation with both component code calculations in the column direction and the row direction as a set or may be determined for the total number of times of component code calculation. It is assumed that the predetermined number of times is determined depending on the performance of the nonvolatile memory 3 or the embodiment, and thus description thereof will not be repeated. When it is determined that the component code word calculation is performed the predetermined number of times (YES in S702), the process flow ends.

On the other hand, when the error correction unit 323 determines that the component code word calculation on the product code is not performed the predetermined number of times (NO in S702), one (the row direction or the column direction) of the component codes forming the product code is selected and the error correction process (code word calculation) on component code words of the selected component code is performed (S703). In the selecting of the component code in S703, for example, when the row direction is first selected, the row direction is selected until the calculation is performed on all the component code words including an error among the component code words in the row direction, and the column direction is selected after the calculation is performed on all the component code words including an error among the component code words in the row direction. The column direction is selected until the calculation is performed on all the component code words including an error among the component code words in the column direction, and the row direction is selected after the calculation is performed on all the component code words including an error among the component code words in the column direction. In this way, the column direction and the row direction are selected so as to alternately perform the calculations in the column direction and the row direction.

Then, the component code determining unit 322 determines whether the code word calculation (error correction process) succeeds (S704). When it is determined that the component code word calculation fails (NO in S704), the process flow moves to S707.

On the other hand, when it is determined that the code word calculation succeeds (YES in S704), the component code determining unit 322 determines whether the error correction calculation accompanies a change of another component code word having common data (S705). For example, as illustrated in FIG. 6, when the data on which error correction is performed (of which a bit value is inverted) by the code word calculation performed in S703 is data on which error correction is performed by the code word calculation of another component code word, it is determined that a change of another component code word is accompanied. When it is determined that a change of another component code word is accompanied (YES in S705), the process flow moves to S707. The specific control of S705 is the same as described with reference to FIG. 6 and description thereof will not be repeated.

On the other hand, when it is determined that the error correction calculation does not accompany a change of another component code word having common data (NO in S705), the component code determining unit 322 determines whether the inversion number in the component code word is equal to or greater than the reference value i (S706). When it is determined that the inversion number is not equal to or greater than the reference value i (NO in S706), the process flow moves to S708.

On the other hand, when the component code determining unit 322 determines that the inversion number in the component code word is equal to or greater than the reference value i (YES in S706), the process flow moves to S707.

The update unit 721 performs the rollback control on component code to be currently calculated using the code word on which the error correction is not yet performed and stored in the received word storage area 311 (S707). The rollback control is also performed on another component code in which the component code to be currently calculated is changed when the calculation in S703 fails, or the rollback control is performed on another component code when a change of another component code word is accompanied in S705.

The error correction unit 323 determines whether all the component code words in the column direction or the row direction are selected (S709). When it is determined that all the component code words in the column direction or the row direction are not selected (NO in S709), the process flow from S703 is performed. On the other hand, when it is determined that all the component code words in the column direction or the row direction are selected (YES in S709), the process flow from S701 is performed.

According to this process flow, when the erroneous correction is performed or when the calculation for the error correction fails, the rollback control is performed and it is thus possible to enhance the probability that correct user data can be acquired. In this embodiment, the rollback control is performed in the case in which it is determined that the component code word calculation fails, in the case in which it is determined that a change of another component code word is accompanied, and in the case in which it is determined that the inversion number in the component code word is equal to or greater than the reference value i. However, the rollback control is not limited to all the three conditions of the case in which it is determined that the component code word calculation fails, the case in which it is determined that a change of another component code word is accompanied, and the case in which it is determined that the inversion number in the component code word is equal to or greater than the reference value i, but the rollback control may be performed in one or two conditions of the three conditions. In addition, one or more conditions of the three conditions may be combined with another condition.

### Second Embodiment

In the first embodiment, the example in which the same rollback control is always performed regardless of the progress of the iterated correction of the product code when there is a possibility that the erroneous correction will occur or when the generation of a code word fails has been described. However, when a component code word of which the erroneous correction is not sure is subjected to the rollback control, the erroneous correction probability is lowered. However, by performing the rollback control on the component code word in which the erroneous correction does not occur, there is a possibility that a delay will occur due to the iterated correction of the product code.

Therefore, in a second embodiment, the rollback control is changed depending on the progress of the iterated correction of a product code.

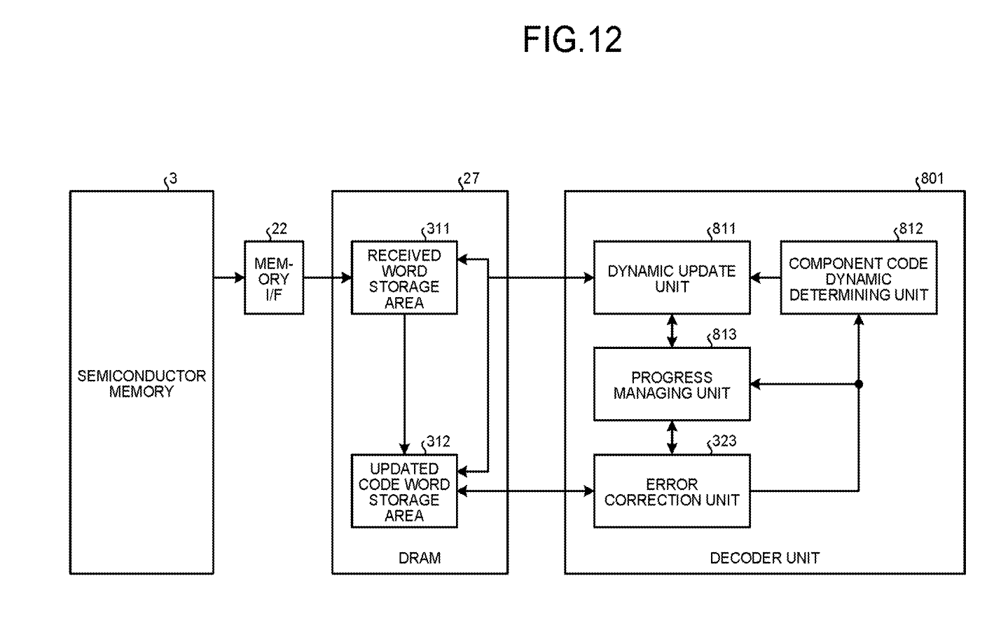

FIG. 12 is a block diagram illustrating a configuration of a decoder unit 801, a DRAM 27, and a nonvolatile memory 3 in the second embodiment. In FIG. 12, a received word storage area 311 and an updated code word storage area 312 are installed in the DRAM 27, similarly to the first embodiment.

The decoder unit 801 includes a dynamic update unit 811, a component code dynamic determining unit 812, a progress managing unit 813, and an error correction unit 323. The decoder unit 801 may be mounted as a processor and may realize the dynamic update unit 811, the component code dynamic determining unit 812, the progress managing unit 813, and the error correction unit 323 by executing a program (not illustrated). The controller 23 may include the dynamic update unit 811, the component code dynamic determining unit 812, the progress managing unit 813, and the error correction unit 323. In the second embodiment, the same elements as in the first embodiment will be referenced by the same reference numerals and description thereof will not be repeated.

The progress managing unit 813 manages the progress of the iterated correction of error correction on a product code by the error correction unit 323. The progress managing unit 813 in this embodiment stores the number of times of iterated error correction of a component code as the progress of the iterated correction.

The component code dynamic determining unit 812 determines whether the result of the error correction performed by the error correction unit 323 satisfies the rollback control condition for each component code word on which the error correction is performed in consideration of the progress.

For example, the reference value i is determined in advance in the first embodiment, but the reference value i varies depending on the progress in the second embodiment.

In this embodiment, the error correction unit 323 alternately iterates the error correction of the plural component code words in the column direction and the error correction of the plural component code words in the row direction. The reference value i is set depending on the number of times of iterated error correction.

In this embodiment, when the number of times of iterated error correction of a component code is less than Threshold value A, the component code dynamic determining unit 812 sets the reference value to i=2. When the number of times of iterated error correction of a component code is equal to or greater than Threshold value A and less than Threshold value B, the component code dynamic determining unit 812 sets the reference value to i=3. When the number of times of iterated error correction of a component code is equal to or greater than Threshold value B, the component code dynamic determining unit 812 sets the reference value to i=4.

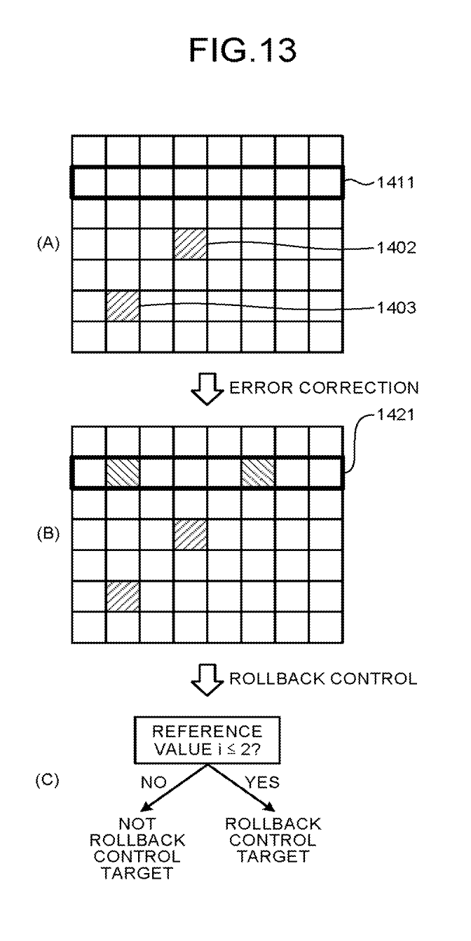

FIG. 13 is a diagram illustrating determination of a rollback control target in the component code dynamic determining unit 812 of this embodiment.

In (A) of FIG. 13, data inverted by the error correction of component code words in the column direction are a plurality of pieces of data 1401 and 1402. A row component code word 1411 in (A) of FIG. 13 is set as an error correction target of the error correction unit 323. A product code as the process result of the error correction target is illustrated in (B) of FIG. 13.

In (B) of FIG. 13, it can be seen that two pieces of inverted data are included in a component code word 1421 in the row direction subjected to the error correction, that is, the inversion number is i=2. The component code dynamic determining unit 812 determines whether the condition of inversion number reference value i is satisfied. The reference value i is determined depending on the number of times of iterated error correction of a component code as described above.

As illustrated in (C) of FIG. 13, the control of the component code dynamic determining unit 812 varies depending on whether the condition of reference value i≦2 is satisfied. That is, when the condition of reference value i≦2 is satisfied, the component code word 1421 is determined to be a rollback control target. On the other hand, when the condition of reference value i>2 is satisfied, the component code word 1421 is determined not to be a rollback control target.

In this way, in the component code dynamic determining unit 812 and the dynamic update unit 811 of this embodiment, the reference value i varies depending on the number of times of iterated error correction which is performed by the error correction unit 323. In this way, the dynamic update unit 811 determines the reference value (threshold value) i based on the number of times of iterated error correction in the error correction unit 323.

That is, when the iterated correction of error correction is performed, it is thought that the error correction has to be surely performed at the first time. Accordingly, the dynamic update unit 811 of this embodiment performs control of setting the first reference value i to be small, carefully performing the error correction, and slowly increasing the reference value i, whereby the error correction capability of a product code can be satisfactorily used.

The component code dynamic determining unit 812 determines the rollback control target based on only the inversion number, but the rollback control (example illustrated in FIG. 6) based on the calculation result of component code words in the other direction which is subsequently performed may vary depending on the progress. Even when the generation of a component code word by the error correction fails, the rollback control target varies depending on the progress.

In this way, in the component code dynamic determining unit 812 and the dynamic update unit 811 of this embodiment, the target to be updated to data on which the error correction is not yet performed varies depending on the number of times of iterated error correction which is performed by the error correction unit 323.

That is, the dynamic update unit 811 performs the rollback control on at least one of data which is not corrected by the error correction in the first direction (for example, the column direction or the row direction) but is corrected by the error correction in the second direction (the column direction or the row direction which is a direction other than the first direction) and data which is corrected by the error correction in the first direction based on the number of times of iterated error correction. The dynamic update unit 811 determines data to be subjected to the rollback control based on the number of times of iterated error correction which is performed by the error correction unit 323. For example, it is thought that both data is set as the rollback control target when the number of times of iteration is small, and any one data is set as the rollback control target when the number of times of iteration is large.

The dynamic update unit 811 updates at least some data forming a component code word on which the error correction is performed by the error correction unit 323 to data on which the error correction is not yet performed and stored in the received word storage area 311. The dynamic update unit 811 of this embodiment performs different rollback control depending on the progress.

In this embodiment, partial rollback control and entire rollback control are performed as the rollback control.

The partial rollback control is control of returning only data common to one component code word to be subjected to the rollback control and another component code word to be subjected to the rollback control to the state on which the error correction is not yet performed.

The entire rollback control is control of returning all data included in one component code word to be subjected to the rollback control and another component code word to be subjected to the rollback control to the state on which the error correction is not yet performed. The rollback control of the first embodiment corresponds to the entire rollback control.

The dynamic update unit 811 performs one of the partial rollback control and the entire rollback control depending on the progress.

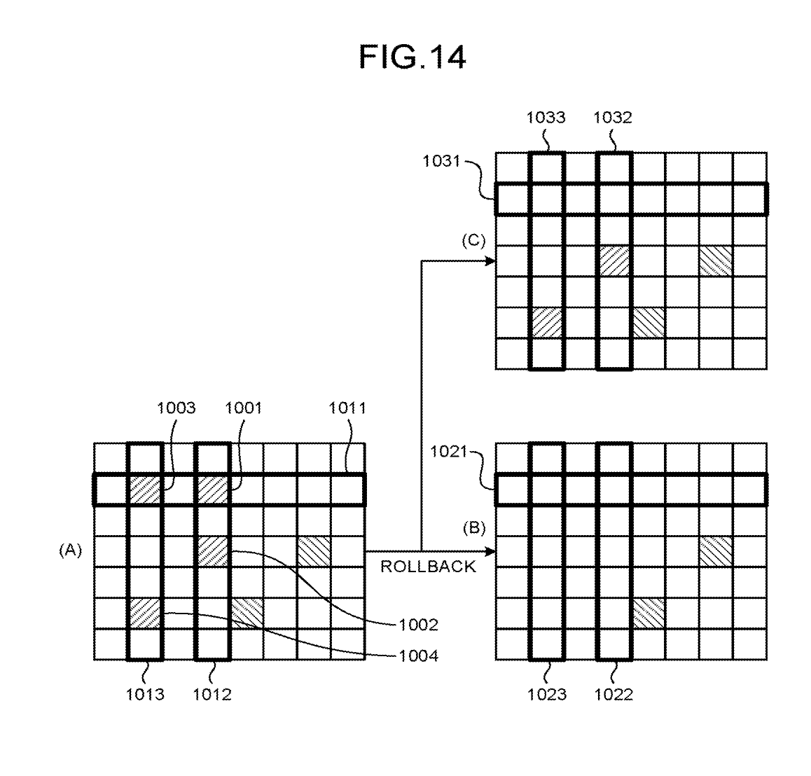

FIG. 14 is a diagram illustrating the rollback control in the dynamic update unit 811 when the generation of a code word by the error correction fails in this embodiment. As illustrated in (A) of FIG. 14, it is assumed that a plurality of pieces of data 1001, 1002, 1003, and 1004 are inverted by the error correction of column component code words 1012 and 1013. It is assumed that a column component code 1011 is processed as the error correction target of the error correction unit 323, the error correction fails, and a code word is not generated. The component code dynamic determining unit 812 determines component code words 1011, 1012, and 1013 to be the rollback control target.

The component code dynamic determining unit 812 performs any one of the partial rollback control and the entire rollback control depending on the progress.

(B) of FIG. 14 illustrates a case in which the entire rollback control is performed. As illustrated in (B) of FIG. 14, it can be seen that all inverted data of at least some data forming the component code words 1011, 1012, and 1013 are returned to data forming the code words on which the error correction is not performed.

That is, the dynamic update unit 811 performs the rollback control on data, on which the error correction is performed, of an arbitrary component code word which is one or more of plural component code words in the first direction (the row direction or the column direction) and which includes bits on which the error correction is performed.

(C) of FIG. 14 illustrates a case in which the partial rollback control is performed. As illustrated in (C) of FIG. 14, it can be seen that a part, which duplicates between the component code word 1011 and other component code words 1012 and 1013, among the inverted data included in the component code words 1011, 1012, and 1013 is returned to the data forming the code words on which the error correction is not performed yet.

The dynamic update unit 811 performs the rollback control on a predetermined bit, on which the error correction is performed, of an arbitrary component code word which is one of plural first component code words in the column direction (or the row direction) and does not update data other than the predetermined bit, on which the error correction is performed in the arbitrary component code word.

In this embodiment, a condition for switching the condition for performing the entire rollback control and the condition for performing the partial rollback control is not particularly limited. For example, the conditions may be switched depending on the number of times of iteration. The condition for performing the rollback control including the entire rollback control or the partial rollback control is, for example, a condition that the error correction of another component code word, which includes a bit on which the error correction is performed among plural bits included in one component code word which is one of the plural component code words in the first direction (the column direction or the row direction) and which is one of the plural component code words in the second direction (the column direction or the row direction which is a direction other than the first direction), fails but may be another condition.

In this way, the component code dynamic determining unit 812 performs different rollback control depending on the progress. In this embodiment, the entire rollback control is performed when the number of times of iterated error correction of a component code is less than Threshold value K, and the partial rollback control is performed when the number of times of iterated error correction of a component code is equal to or greater than Threshold value K. Threshold value K is set depending on the embodiments.

In the first embodiment, an example in which the entire rollback control is performed without depending on the progress is described, but the partial rollback control is performed every time when the rollback control is necessary without depending on the progress in a modified example.

In the first embodiment, an example in which one component code word on which the error correction is performed and another component code word having data common to the one component code word are set as the rollback control target. However, the rollback control target is not limited to the component codes, but component codes may be recursively determined.

The component code dynamic determining unit 812 of the second embodiment recursively determines a component code word as a rollback control target based on the order of error correction.

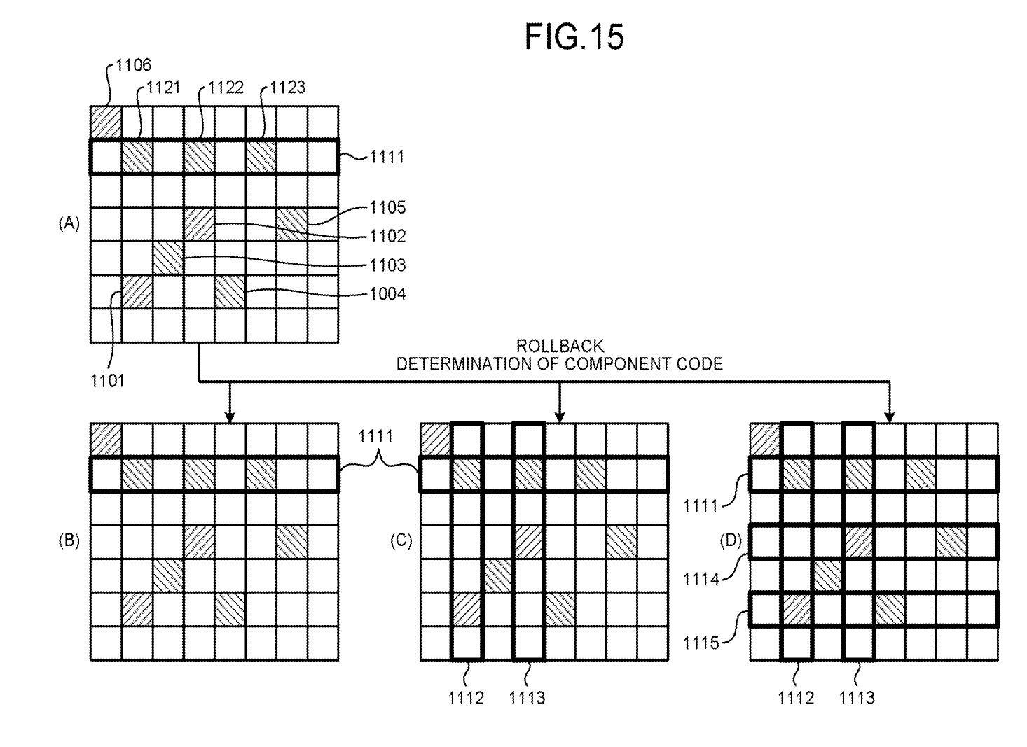

FIG. 15 is a diagram illustrating a flow of recursively determining a component code word to be subjected to the rollback control in the component code dynamic determining unit 812 of the second embodiment. In (A) of FIG. 15, it is assumed that the error correction is performed on a component code word 1111. In this error correction, bit values of pieces of data 1121, 1122, and 1123 included in the component code word 1111 are inverted (corrected). The component code dynamic determining unit 812 recursively determines the rollback control target from the component code word 1111 on which the error correction is performed. In the example illustrated in FIG. 15, it is assumed that the bit values are inverted (corrected) by performing the error correction in the row direction on a plurality of pieces of data 1101, 1102, and 1106, and the bit values are inverted (corrected) by performing the error correction in the column direction on a plurality of pieces of data 1103, 1104, and 1105.

(B) of FIG. 15 illustrates a case in which the number of recursion stages is equal to 0. That is, since the recursion is not performed, the component code dynamic determining unit 812 determines only the component code word 1111 in the row direction as the rollback control target. Accordingly, the number of component codes to be subjected to the rollback control is 1.

(C) of FIG. 15 illustrates a case in which the number of recursion stages is equal to 1. Therefore, the component code dynamic determining unit 812 determines the component code word 1111 in the row direction and the component code words 1112 and 1113 in the column direction which share data having an inverted (corrected) bit value with the component code word 1111 and which includes other data having an inverted (corrected) bit value as the rollback control target. Accordingly, the number of component codes to be subjected to the rollback control is 3.

In this embodiment, when the number of recursion stages is two or more, the received word storage area 311 of the DRAM 27 stores a change history of the component code words forming a product code depending on the number of recursion stages. Since the data 1106 of FIG. 15 is not associated with the recursive rollback control from the plurality of pieces of data 1121, 1122, and 1123 included in the component code word 1111 without depending on the number of recursion stages, the inversion (correction) of bit values is not performed.

(D) of FIG. 15 illustrates a case in which the number of recursion stages is equal to 2. The component code dynamic determining unit 812 determines the component code words 1111, 1112, and 1113 illustrated in (C) of FIG. 15 and the component code words 1114 and 1115 in the row direction which share data having an inverted (corrected) bit value with the component code words 1112 and 1113 in the column direction and which includes other data having an inverted (corrected) bit value as the rollback control target. Accordingly, the number of component code words to be subjected to the rollback control is 5.

In the example illustrated in FIG. 15, the number of recursion stages ranges from 0 to 2, but the number of recursion stages may be 3 or greater.

In this way, the dynamic update unit 811 of this embodiment performs the rollback control on data, on which the error correction is performed, of one component code word when the rollback control condition is satisfied by the error correction of the one component code word which is one of the plural component code words in the first direction (the column direction or the row direction). Then, the dynamic update unit 811 recursively performs the rollback control of data, on which the error correction is performed, of the plural component code words in the second direction (the column direction or the row direction which is a direction other than the first direction) and the rollback control on data, on which the error correction is performed, of the plural component code words in the first direction.

The component code dynamic determining unit 812 of this embodiment determines the number of recursion stages depending on the progress of the iterated correction. In a more specific example, the number of recursion stages is determined depending on whether the number of times of iterated error correction of a component code word is equal to or greater than a threshold value set for each recursion stage.

The component code dynamic determining unit 812 does not limit the number of recursion stages when the number of times of iterated error correction of a component code word is less than Threshold value A′. The component code dynamic determining unit 812 sets the number of recursion stages to 2 when the number of times of iterated error correction of a component code word is equal to or greater than Threshold value A′ and less than Threshold value B′. The component code dynamic determining unit 812 sets the number of recursion stages to 1 when the number of times of iterated error correction of a component code word is equal to or greater than Threshold value B′ and less Threshold value C′. The component code dynamic determining unit 812 sets the number of recursion stages to 0, that is, does not recursively perform the rollback control when the number of times of iterated error correction of a component code word is equal to or greater than Threshold value C′.

In this way, the dynamic update unit 811 of this embodiment recursively iterates a process of updating first data included in a first code word which is a component code word in one direction among component code words in the row direction and the column direction forming a product code to second data on which the error correction is not yet performed, and then updating arbitrary data included in a second code word on which the error correction is performed before the first code word on which the error correction is performed to data on which the error correction is not yet performed based on a predetermined number of recursion stages.

In this embodiment, the number of times of recursion is first set to be great so as to improve the certainty of the error correction. Thereafter, by slowly decreasing the number of times of recursion, a processing load caused in the recursion is reduced. Accordingly, in this embodiment, it is possible to make improvement in certainty of error correction and reduction in processing load compatible with each other.

Whether the partial rollback control should be performed or the entire rollback control should be performed after the component code to be subjected to the rollback control is recursively determined is not particularly limited, but may be determined depending on the progress of the iterated correction.

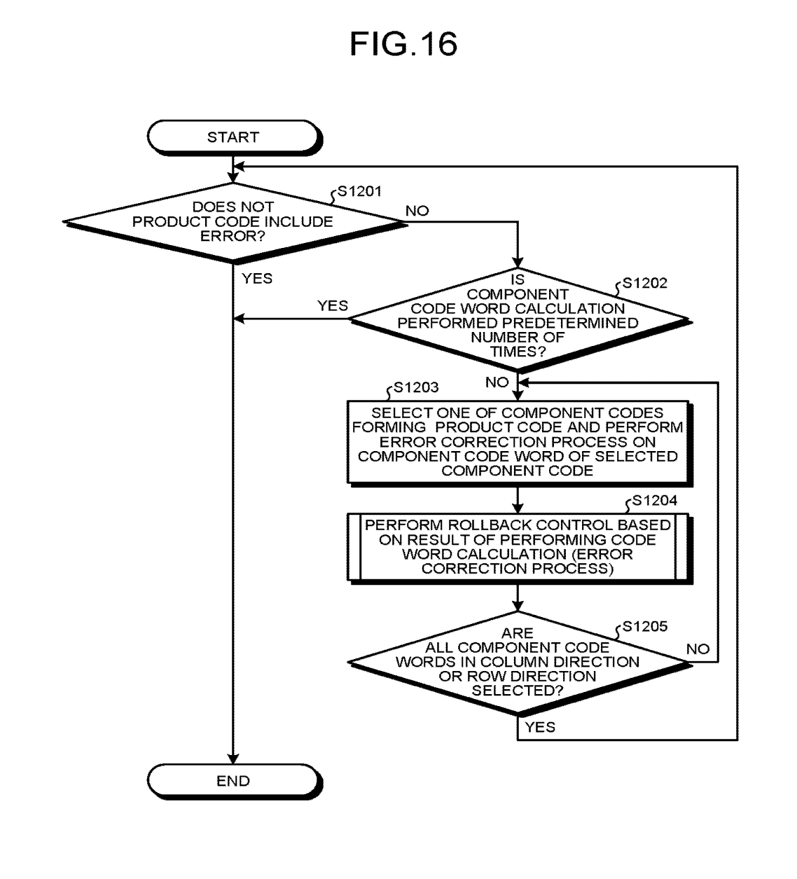

The process flow up to the rollback control in the memory controller 2 according to this embodiment will be described below. FIG. 16 is a flowchart illustrating the process flow in the memory controller 2 according to this embodiment. Before the process flow illustrated in FIG. 16, it is assumed that a product code stored in the nonvolatile memory 3 is loaded to the received word storage area 311 and then the product code is copied to the updated code word storage area 312 in accordance with a command from the host 4.

First, the error correction unit 323 of the decoder unit 26 determines whether the product code stored in the updated code word storage area 312 does not include an error (S1201). In S1201 of the first time, for example, all the component code words in the row direction are decoded and it is determined whether the product code does not include an error based on information on error presence or absence acquired by the decoding. When the error correction unit 323 determines that the product code does not include an error (YES in S1201), the process flow ends.

On the other hand, when the error correction unit 323 of the decoder unit 26 determines that the product code includes an error (NO in S1201), the error correction unit 323 determines whether calculation (error correction process) of the component codes in the column direction and the row direction on the product code is performed a predetermined number of times (S1202). The predetermined number of times may be determined for the number of times of calculation of the component codes with calculation both component codes in the column direction and the row direction as a set, or may be determined for the total number of times of calculation of the component codes. The predetermined number of times is determined depending on the performance of the nonvolatile memory 3 or the embodiments, and thus description thereof will not be made. When it is determined that the calculation of component code words is performed the predetermined number of times (YES in S1202), the process flow ends.

On the other hand, when the error correction unit 323 determines that the calculation of code words on the product code is not performed the predetermined number of times (NO in S1202), one (the row direction or the column direction) of the component codes forming the product code is selected and the error correction process (code word calculation) of the component code words of the selected component code is performed (S1203).

The decoder unit 801 performs the rollback control based on the result of performing the code word calculation (error correction process) (S1204). The detailed process flow will be described later.

The error correction unit 323 determines whether all the component code words in the column direction or the row direction are selected (S1205). When it is determined that all the component code words in the column direction or the row direction are not selected (NO in S1205), the process flow from S1203 is performed. On the other hand, when it is determined that all the component code words in the column direction or the row direction are selected (YES in S1205), the process flow from S1201 is performed.

Based on the above-mentioned process flow, since the rollback control is performed after the code word calculation (error correction process), it is possible to enhance the probability that correct user data can be acquired.

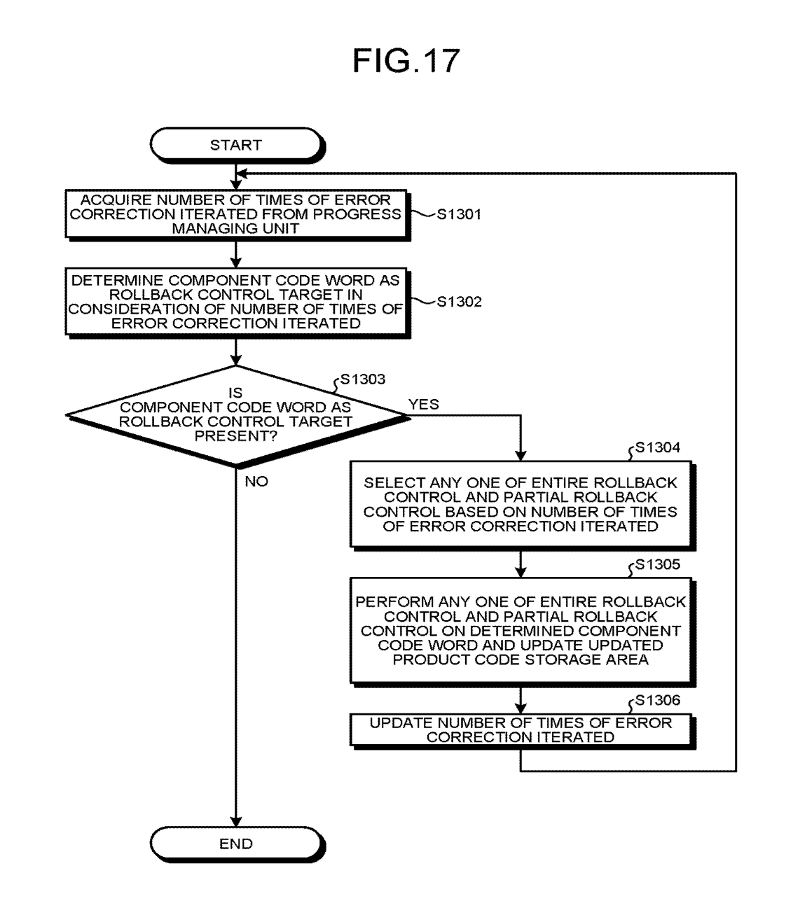

The rollback control illustrated in S1204 in the decoder unit 801 of this embodiment will be described below. FIG. 17 is a flowchart illustrating the process flow in the decoder unit 801 of this embodiment.

First, the component code dynamic determining unit 812 acquires the number of times of iterated error correction from the progress managing unit 813 (S1301).

Then, the component code dynamic determining unit 812 determines a component code word to be subjected to the rollback control based on the number of times of iterated error correction (S1302). For example, the component code word to be subjected to the rollback control is determined in consideration of the inversion number besides the number of times of iterated error correction, or the component code word to be subjected to the rollback control is determined based on the number of recursion stages based on the number of times of iterated error correction.

Then, the dynamic update unit 811 determines whether a component code word to be subjected to the rollback control is present (S1303). When it is determined that the component code word is not present (NO in S1303), the process flow ends.

On the other hand, when it is determined that the component code word to be subjected to the rollback control is present (YES in S1303), the dynamic update unit 811 acquires the number of times of iterated error correction from the progress managing unit 813 and selects one of the entire rollback control and the partial rollback control based on the number of times of iterated error correction (S1304).

Then, the dynamic update unit 811 performs the selected one of the entire rollback control and the partial rollback control on the component code word to be subjected to the rollback control and updates the updated code word storage area 312 (S1305). Accordingly, the rollback control on the component code words of the component codes of the product code stored in the updated code word storage area 312 is performed.

Then, the dynamic update unit 811 updates the number of times of iterated error correction of the progress managing unit 813 (S1306) and restarts the process flow from S1301.

Based on the above-mentioned process flow, the rollback control can be performed depending on the progress of the number of times of iteration.

The second embodiment is not limited to the above-mentioned control, but the method of determining a component code may be changed depending on the progress of the number of times of iteration.

For example, the rollback control when calculation for the error correction of a component code word succeeds and a code word is generated and the rollback control when the code word calculation (error correction process) of a component code word fails and a code word is not generated may be selected depending on the progress of the iterated correction.

Specifically, 1) a component code word to be subjected to the rollback control is determined in both cases of a case in which the code word calculation (error correction process) of a component code word succeeds and a code word is generated and a case in which the code word calculation (error correction process) of a component code word fails and a code word is not generated.

2) The rollback control is not performed and a component code word to be subjected to the rollback control is not determined in both cases of the case in which the code word calculation (error correction process) succeeds and a code word is generated and a case in which the code word calculation (error correction process) fails and a code word is not generated.

3) A component code word to be subjected to the rollback control is determined in only the case in which the code word calculation (error correction process) succeeds and a code word is generated.

4) A component code word to be subjected to the rollback control is determined in only the case in which the code word calculation (error correction process) fails and a code word is not generated.

For example, the component code dynamic determining unit 812 may dynamically select one of 1) to 4) depending on the progress of the iterated correction.

The rollback control in the case in which the code word calculation (error correction process) succeeds and a code word is generated may be performed in various aspects in which a change of another component code word is accompanied or the inversion number exceeds the reference number. Therefore, in this embodiment, determination of a component code word to be subjected to the rollback control may be switched in the aspects depending on the progress of the number of times of iteration.

Specifically, 5) a component code word to be subjected to the rollback control is determined in both cases of a case in which a change of another component code word is accompanied and a case in which the inversion number exceeds the reference number.

6) The rollback control is not performed and a component code word to be subjected to the rollback control is not determined in both cases of the case in which a change of another component code word is accompanied and the case in which the inversion number exceeds the reference number.

7) A component code word to be subjected to the rollback control is determined in only the case in which a change of another component code word is accompanied.

8) A component code word to be subjected to the rollback control is determined in only the case in which the inversion number exceeds the reference number.

In the second embodiment, the component code dynamic determining unit 812 may dynamically select any one of 1) to 8) depending on the progress of the iterated correction when the rollback control is performed in the case in which the code word calculation (error correction process) succeeds and a code word is generated.

In the above-mentioned embodiment, it is possible to enhance a success rate of error correction of an entire product code by performing rollback control on a component code having a high possibility that erroneous correction occurs.

However, when the rollback control is performed on a component code word in which erroneous correction does not occur, there is a possibility that the iterated correction will not proceed.

Therefore, in this embodiment, one or more of the method of determining a component code word to be subjected to the rollback control and the rollback control method is dynamically changed depending on the progress of the iterated correction. Accordingly, it is possible to make enhancement in the success rate of error correction and suppression of the possibility that the iterated correction will not proceed compatible with each other.

In the above-mentioned embodiment, the control of discarding data having a high possibility that it is erroneous among the error correction results and updating the data to data on which the error correction is not yet performed by performing the above-mentioned control. Accordingly, it is possible to reduce the erroneous correction.

Accordingly, in the above-mentioned embodiment, it is possible to enhance a success probability of the error correction of a product code by reducing the erroneous correction.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a nonvolatile memory;
a correction unit configured to perform error correction on a code word forming a product code that is read from the nonvolatile memory;
a storage unit configured to store a first code word, the first code word being the code word on which the error correction is not yet performed by the correction unit; and
an update unit configured to update, in case where a condition is satisfied, first data to second data, the first data being included in a second code word, the second code word being the code word on which the error correction is performed, the first data being corrected by the error correction, the second data being included in the first code word stored in the storage unit, the second data corresponding to the first data.

2. The memory system according to claim 1, wherein the code word includes a plurality of first component code words and a plurality of second component code words,
the first component code words are generated based on fourth data including a plurality of pieces of third data,
the second component code words are generated based on fifth data including the plurality of pieces of third data, each of the plurality of pieces of third data being selected from the respective pieces of fourth data, and
the third data included in one piece of fifth data does not duplicate with the third data included in another piece of fifth data.

3. The memory system according to claim 2, wherein the condition is a condition that the number of data on which the error correction is performed by the correction unit is equal to or greater than a threshold value, the data being included in the code words.

4. The memory system according to claim 3, wherein the correction unit alternately iterates the error correction of the first component code words and the error correction of the second component code words, and
the update unit determines the threshold value based on the number of times of error correction iterated by the correction unit.

5. The memory system according to claim 2, wherein the condition is a condition that the fifth data is corrected through the error correction of a fourth component code word including the fifth data, the fifth data not being corrected through the error correction among the plurality of pieces of third data included in a third component code word that is one of the first component code words, the fourth component code word being one of the second component code words, and
the update unit updates at least one of the fifth data and sixth data to data on which the error correction is not yet performed, the sixth data being corrected through the error correction of the plurality of pieces of third data included in the third component code word.

6. The memory system according to claim 5, wherein the correction unit alternately iterates the error correction of the first component code words and the error correction of the second component code words, and
the update unit determines the data to be updated based on the number of times of error correction iterated by the correction unit.

7. The memory system according to claim 2, wherein the condition is a condition that the error correction of a fourth component code word fails, the fourth component code word being one of the second component code words and including the fifth data on which the error correction is performed among the plurality of pieces of third data included in a third component code word that is one of the plurality of first component code words, and
the update unit updates seventh data to the data on which the error correction is not yet performed, the seventh data being the data on which the error correction of the third component code word is performed.

8. The memory system according to claim 2, wherein
the update unit updates, in case where the condition is satisfied by the error correction of the third component code word, the fifth data to the data on which the error correction is not performed, the fifth data being the data on which the error correction of a third component code word that is one of the first component code words, and
the update unit recursively performs a first update and a second update, the first update updating the data on which the error correction of the plurality of second component code words is performed to the data on which the error correction is not yet performed, the second update updating the data on which the error correction of the first component code words is performed to the data on which the error correction is not yet performed.

9. The memory system according to claim 2, wherein the condition is a condition that the error correction of a fourth component code word fails, the fourth component code word being one of the second component code words and including the fifth data on which the error correction is performed among the plurality of pieces of third data included in a third component code word that is one of the first component code words, and
the update unit updates the fifth data on which the error correction of the third component code word is performed to the data on which the error correction is performed and does not update data other than the fifth data, the data being the data on which the error correction of the third component code word is performed.

10. The memory system according to claim 2, wherein the condition is a condition that the error correction of a fourth component code word fails, the fourth component code word being one of the second component code words and including the fifth data on which the error correction is performed among the plurality of pieces of third data included in a third component code word that is one of the first component code words, and
the update unit updates eighth data to the data on which the error correction is not yet performed, the eighth data being the data on which the error correction of the third component code word including the fifth data is performed.

11. A memory controller comprising:
a correction unit configured to perform error correction on a code word forming a product code that is read from a nonvolatile memory;
a storage unit configured to store a first code word, the first code word being the code word on which the error correction is not yet performed by the correction unit; and
an update unit configured to update, in case where a condition is satisfied, first data to second data, the first data being included in a second code word, the second code word being the code word on which the error correction is performed, the first data being corrected by the error correction, the second data being included in the first code word stored in the storage unit, the second data corresponding to the first data.

12. The memory controller according to claim 11, wherein the code word includes a plurality of first component code words and a plurality of second component code words,
the first component code words are generated based on fourth data including a plurality of pieces of third data,
the second component code words are generated based on fifth data including the plurality of pieces of, each of the plurality of pieces of third data being selected from the respective pieces of fourth data, and
the third data included in one piece of fifth data does not duplicate with the third data included in another piece of fifth data.

13. The memory controller according to claim 12, wherein the condition is a condition that the number of data on which the error correction is performed by the correction unit is equal to or greater than a threshold value, the data being included in the code words.

14. The memory controller according to claim 13, wherein the correction unit alternately iterates the error correction of the first component code words and the error correction of the second component code words, and
the update unit determines the threshold value based on the number of times of error correction iterated by the correction unit.

15. The memory controller according to claim 12, wherein the condition is a condition that the fifth data is corrected through the error correction of a fourth component code word including the fifth data, the fifth data not being corrected through the error correction among the plurality of pieces of third data included in a third component code word that is one of the first component code words, the fourth component code word being one of the second component code words, and
the update unit updates at least one of the fifth data and sixth data to data on which the error correction is not yet performed, the sixth data being corrected through the error correction of the plurality of pieces of third data included in the third component code word.

16. A method of controlling a nonvolatile memory, the method comprising:
reading a code word from the nonvolatile memory;
performing error correction on the read code word;
storing a first code word in a storage unit, the first code word being the read code word on which the error correction is not yet performed; and
updating, in case where a condition is satisfied, first data to second data, the first data being included in a second code word, the second code word being the code word on which the error correction is performed, the first data being corrected by the error correction, the second data being included in the first code word stored in the storage unit, the second data corresponding to the first data.

17. The method according to claim 16, wherein the code word includes a plurality of first component code words and a plurality of second component code words,
the first component code words are generated based on fourth data including a plurality of pieces of third data,
the second component code words are generated based on a fifth data including the plurality of pieces of third data, each of the plurality of pieces of third data being selected from the respective fourth data, and
the third data included in one piece of fifth data does not duplicate with the third data included in another piece of fifth data.

18. The method according to claim 17, wherein the condition is a condition that the number of data on which the error correction is performed is equal to or greater than a threshold value, the data being included in the code words.

19. The method according to claim 18, wherein the performing error correction includes alternately iterating the error correction of the first component code words and the error correction of the second component code words, and
the updating includes determining the threshold value based on the number of times of error correction iterated.

20. The method according to claim 17, wherein the condition is a condition that the fifth data is corrected through the error correction of a fourth component code word including the fifth data, the fifth data not being corrected through the error correction among the plurality of pieces of third data included in a third component code word that is one of the first component code words, the fourth component code word being one of the second component code words, and
the updating includes updating at least one of the fifth data and sixth data to data on which the error correction is not yet performed, the sixth data being corrected through the error correction of the plurality of pieces of third data included in the third component code word.
